(19) United States
(12) Patent Application Publication
(10) Pub. No.: US 2014/0254094 A1
(43) Pub. Date: Sep. 11, 2014

(54) Assembly Structure with Filter Device and Printed Circuit Board and Welding Method for Making the Same

(71) Applicants: U. D. ELECTRONIC CORP., Taoyuan City (TW); DONGGUAN JIAN GUAN PLASTIC ELECTRONIC CO., LTD., Dongguan City (CN); U. D. (ZHONG JIANG) ELECTRONIC CORP., Deyang City (CN)

(72) Inventors: Chih-Kai Chang, Taoyuan (TW); Tao Guo, Dongguan City (CN)

(73) Assignees: U. D. ELECTRONIC CORP., Taoyuan City (TW); DONGGUAN JIAN GUAN PLASTIC ELECTRONIC CO., LTD., Dongguan City (CN); U. D. (ZHONG JIANG) ELECTRONIC CORP., Deyang City (CN)

(21) Appl. No.: 14/191,728

(22) Filed: Feb. 27, 2014

(30) Foreign Application Priority Data
Mar. 6, 2013 (CN) 201310070964.9
May 15, 2013 (CN) 201320263816.4

(51) Int. Cl. H05K 13/04; H05K 7/14

(52) U.S. Cl. CPC H05K 13/04; H05K 7/14
USPC 361/692; 361/748; 228/170; 228/164

(57) ABSTRACT

The present invention relates to an assembly structure with filter device and printed circuit board and a welding method for making the same. The welding method is firstly make the metal lines of at least one filter devices be disposed in the metal notches formed on at least one edges of the printed circuit board, and then respectively remove the insulation layers covering the metal lines; therefore, the welding metal lines can be respectively welded with the metal notches after the metal lines and the metal notches are treated with a dip soldering process. Thus, the welding process of the filter device and the printed circuit board can be carried out on the edges of the printed circuit board by simple process procedures; moreover, the fabrication yield of the assembly structure can be effectively increased, and the manufacturing time and cost of the assembly structure can be simultaneously reduced.

### BACKGROUND OF THE INVENTION

1. Field of the Invention

The present invention relates to the technology field of electrical connectors, and more particularly to an assembly structure with filter device and printed circuit board and a welding method for making the same.

2. Description of the Prior Art

Nowadays, electrical connectors are commonly provided with filter circuits (or units) for blocking or preventing the influences caused by external noise signal. However, because the size of the conventional filter device is gradually designed and fabricated to be smaller than the size of the traditional filter device, that enhances the difficulty and assembling cost for disposing the conventional filter devices onto the printed circuit boards.

In the conventional technologies, the filters 1′ shown in FIG. 1 are welded to the welding pads 2′ of the PCB 3′ by handwork or using specific welding machine; moreover, before welding the filters 1′ onto the PCB 3′, it needs to scrape the insulation layers 12′ from the metal lines 11′ of the filters 1′, so as to ensure a greater electrical connection produced between the metal lines 11′ and the welding pads 2′ after the filters 1′ have been welded on the PCB 3′.

Through above descriptions, it is able to find that the welding ways for welding the filters 1′ onto the PCB 3′ is very complex, such that the engineers must spend much time for finishing the welding ways. Besides, if the insulation layers 12′ do not be fully removed from the metal lines 11′, the filters 1′ welded on the PCB 3′ cannot work normally due to the disconnection of the metal lines 11′ and the welding pads 2′.

Accordingly, in view of the welding ways for welding the filters 1′ onto the PCB 3′ still including drawbacks and shortcomings, the inventor of the present application has made great efforts to make inventive research thereon and eventually provided an assembly structure with filter device and printed circuit board and welding method for making the same.

### SUMMARY OF THE INVENTION

The primary objective of the present invention is to provide an assembly structure with filter device and printed circuit board and a welding method for making the same, in which, The welding method is firstly make the metal lines of at least one filter devices be disposed in the metal notches formed on at least one edges of the printed circuit board, and then respectively remove the insulation layers covering the metal lines; therefore, the welding metal lines can be respectively welded with the metal notches after the metal lines and the metal notches are treated with a dip soldering process. Thus, the welding process of the filter device and the printed circuit board can be carried out on the edges of the printed circuit board by simple process procedures; moreover, the fabrication yield of the assembly structure can be effectively increased, and the manufacturing time and cost of the assembly structure can be simultaneously reduced.

Accordingly, to achieve the primary objective of the present invention, the inventor of the present invention provides an assembly structure with filter device and printed circuit board, comprising: at least filter device, having a plurality of metal lines covered by an insulation layer; and at least one printed circuit board, provided with a plurality of metal notches on at least one edge thereof, and formed with a circuit layout on the surface thereof. Wherein the metal notches are electrically connected to the circuit layout, and the metal lines are disposed in the metal notches, respectively. Moreover, the metal lines are respectively welded in the metal notches by way of dip soldering process after removing the insulation layers from the metal lines.

Moreover, for achieving the primary objective of the present invention, the inventor of the present invention also provides a welding method for making the assembly structure with filter device and printed circuit board, comprising the following steps:

(1) providing the printed circuit board having the plurality of metal notches on the at least one edges thereof, and making the metal notches electrically connect to the circuit layout formed on the surface of the printed circuit board;
(2) disposing the at least one filter device in the container and disposing the printed circuit board on the two sides of the container, so as to make the metal lines of the filter device respectively received by the metal notches and contact with the metal notches;
(3) filling a colloidal substance into the container for covering the filter device and fixing the metal lines, wherein the air in the container would flow out via the at least one exhaust opening when the colloidal substance is filled in to the container;
(4) treating the metal lines respectively contacting with the metal notches with a laser beam, so as to remove the insulation layers respectively covering the metal lines; and
(5) treating the metal lines and the metal notches with a dip soldering process for welding metal lines with the metal notches, respectively.

Besides, in order to achieve the primary objective of the present invention, the inventor of the present invention further provides another welding method for making the assembly structure with filter device and printed circuit board, comprising the following steps:

(1a) providing the printed circuit board having the plurality of metal notches on the at least one edges thereof, and making the metal notches electrically connect to the circuit layout formed on the surface of the printed circuit board;

(2a) disposing the at least one filter device in the container and disposing the printed circuit board on the two sides of the container, so as to make the two metal lines of the filter device respectively received by the metal notches and contact with the metal notches;

(3a) filling a colloidal substance into the container for covering the filter device and fixing the metal lines, wherein the air in the container would flow out via the at least one exhaust opening when the colloidal substance is filled in to the container;

(4a) disposing the printed circuit board into a tin melting furnace, so as to remove the insulation layers respectively covering the metal lines through a high-temperature solder material in the tin melting furnace; and

(5a) treating the metal lines and the metal notches with a dip soldering process for welding metal lines with the metal notches, respectively.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 is a stereo view of a conventional assembly structure with filters and printed circuit board;

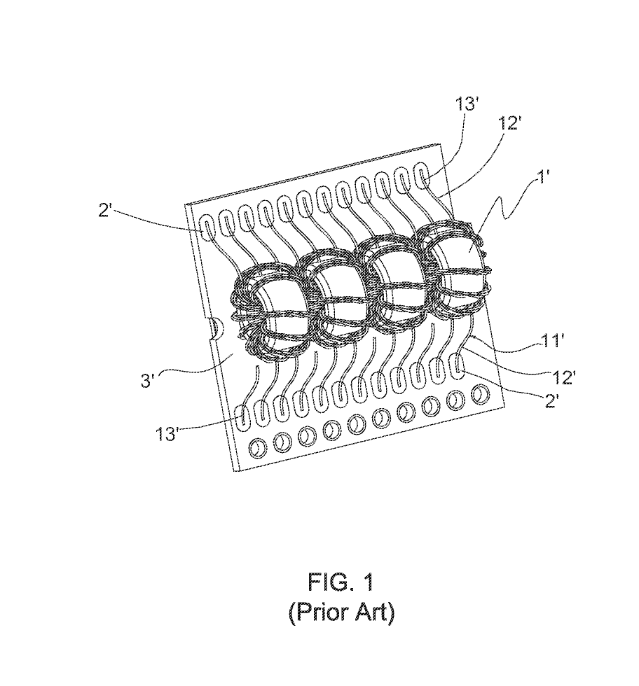

FIG. 2 is a stereo view of an assembly structure with filter devices and printed circuit board according to the present invention;

FIG. 3 is a cross-sectional view of a metal line;

FIG. 4 is a side view of the assembly structure with filter device and printed circuit board;

FIG. 5 is a stereo view of the filter device;

FIG. 6 is a stereo view of a third embodiment of the assembly structure with filter devices and printed circuit board according to the present invention;

FIG. 7 is an exploded view of the third embodiment;

FIG. 8 is a stereo view of a container;

FIG. 9 is a cross-sectional view of the container;

FIG. 10 is a cross-sectional view of the container and a tin melting furnace;

FIG. 11 is flow chart of a welding method for making assembly structure with filter device and printed circuit board; and

FIG. 12 is flow chart of another welding method for making assembly structure with filter device and printed circuit board.

### DETAILED DESCRIPTION OF THE PREFERRED EMBODIMENTS

To more clearly describe an assembly structure with filter device and printed circuit board and welding method for making the same according to the present invention, embodiments of the present invention will be described in detail with reference to the attached drawings hereinafter.

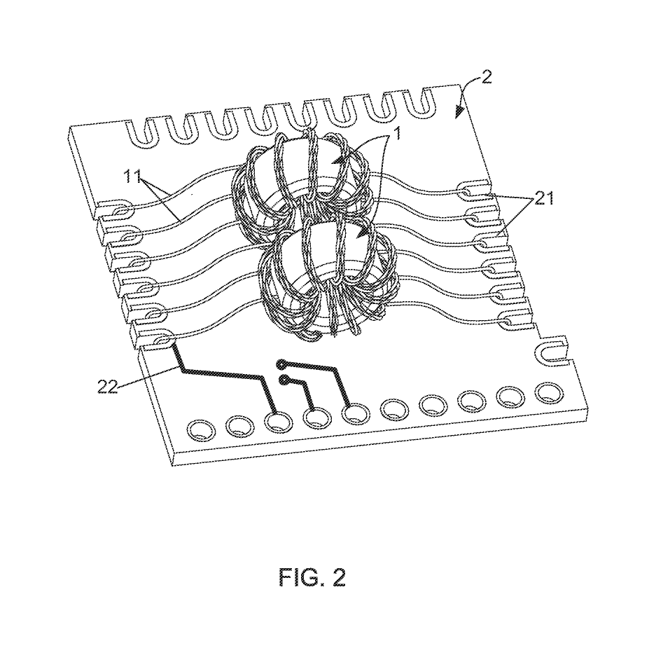

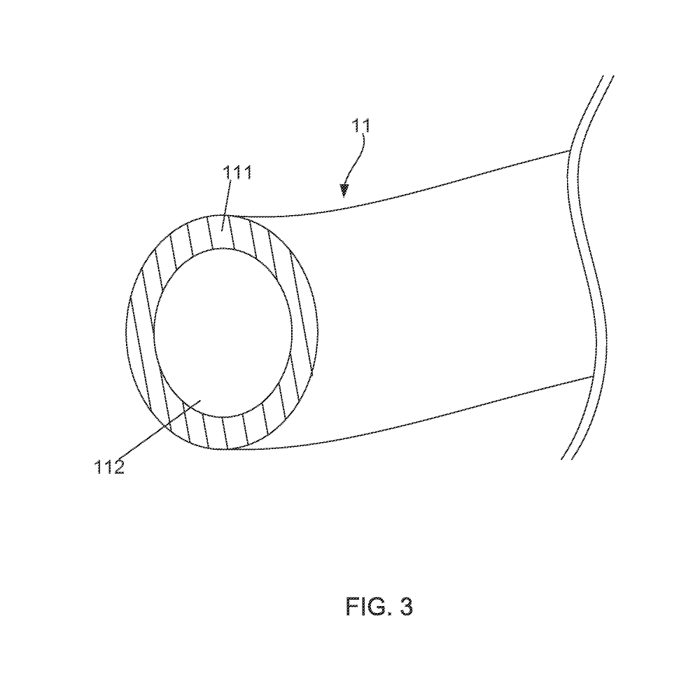

With reference to FIG. 2, which illustrates a stereo view of an assembly structure with filter devices and printed circuit board. Moreover, please simultaneously refer to FIG. 3, there is shown a cross-sectional view of a metal line. As shown in FIG. 2 and FIG. 3, the assembly structure of with filter devices and printed circuit board proposed by the present invention consists of: a plurality of filter devices 1 and a printed circuit board (PCB) 2, wherein the filter devices 1 are disposed on the PCB 2 and has a plurality of metal lines 11. As FIG. 3 shows, each metal line 11 is consisted by an insulation layer 111 and a copper line 112 covered by the insulation layer 111. In addition, as FIG. 2 shows, the edges of the PCB 2 are formed with a plurality of metal notches 21 for respectively receiving the metal lines 11. In the present invention, each metal notch 21 is disposed with a copper sheet or coated with a copper layer for making the metal notch 21 electrically connecting to a circuit layout 22 formed on the surface of the PCB 2, and simultaneously electrically connecting to the metal lines, respectively.

Herein, it needs to further explain that, although FIG. 2 illustrates numerous filter devices 1 disposed on the PCB 2, that does not used for limiting the exemplary embodiment of the filter devices 1; in other application, the PCB 2 can also be disposed with just one filter device 1.

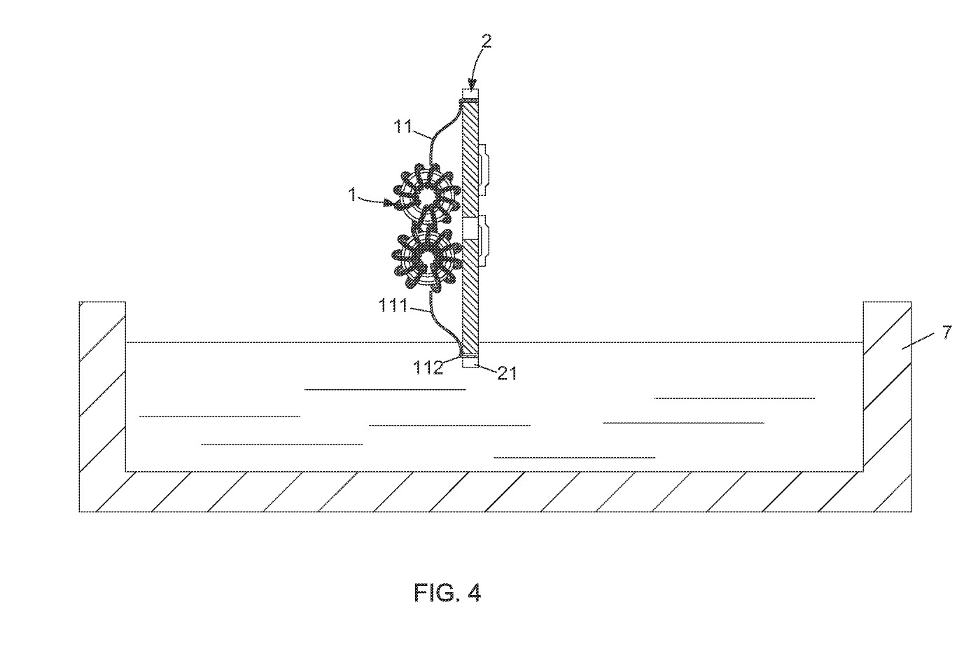

With reference to FIG. 2, and please simultaneously refer to FIG. 4, there is shown a side view of the assembly structure with filter device and printed circuit board. As shown in FIGs., the two metal lines of each the filter device 1 are welded in the metal notch 21 of the PCB 2 by using the following welding steps:

First of all, to provide the printed circuit board (PCB) 2 having the plurality of metal notches 21 on the at least one edges thereof, so as to make the metal lines 11 of the filter devices 1 be disposed in the metal notches 21 and respectively contact with the metal notches 21. Next, to treat the metal lines 11 respectively with a laser beam, so as to remove the insulation layers 111 respectively covering the metal lines 11, and then the copper line 112 of the metal line 11 is shown. After that, the PCB 2 is disposed into a tin melting furnace 7, so as to treat the copper lines 112 and the metal notches 21 with a dip soldering process for welding copper lines 112 with the metal notches 21, respectively.

Inheriting to above descriptions, besides using laser beam to remove the insulation layer 111 of the metal line 11, the insulation layers 111 can also be respectively removed from the metal lines 11 through a high-temperature solder material in the tin melting furnace 7. Thus, comparing to the SMT or DIP technique of conventional assembling method used for assembling the filter devices and the PCB, above-mentioned two ways for removing the insulation layer 111 out of the metal line 11 can facilitate the assembly between the filter devices 1 and the PCB 2 be more simple and convenient, and make the welding process of the filter devices 1 and the PCB 2 be carried out on the edges of the PCB 2 by simple process procedures. Moreover, the fabrication yield of the assembly structure with the filter devices 1 and the PCB 2 can be effectively increased, and the manufacturing time and cost of the assembly structure can be simultaneously reduced.

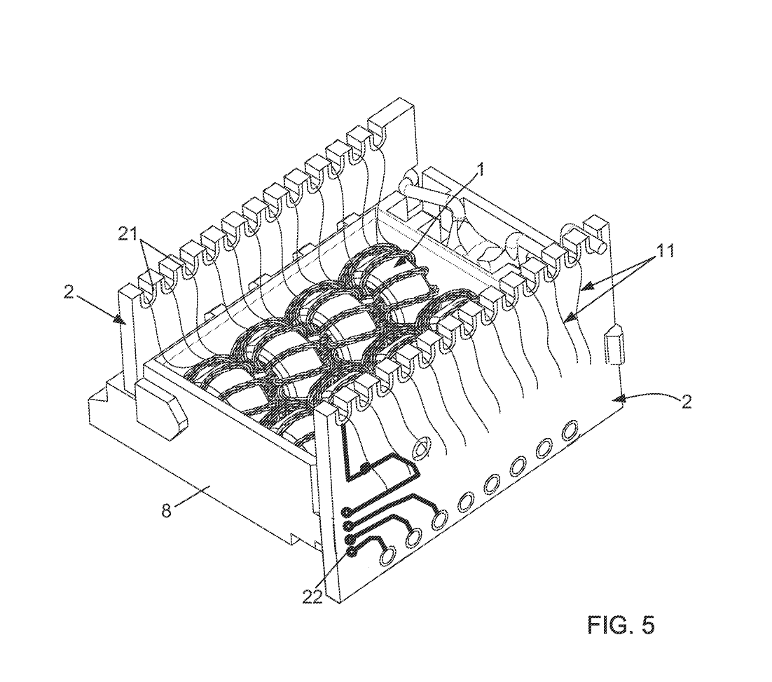

Please refer to FIG. 5, there is shown a stereo view of the filter device 1, the PCB 2, and a base 8. As shown in FIG. 5, the second embodiment of the present invention consists of: numerous filter devices 1, two PCBs 2 and one base 8, wherein the two PCBs 2 are disposed on the two sides of the base 8, and electrically connect to the filter devices 2 for respectively processing input signal and output signal. The embodiment of the present invention shown in FIG. 2 is applied in connector technology filed, for example, RJ45 connector.

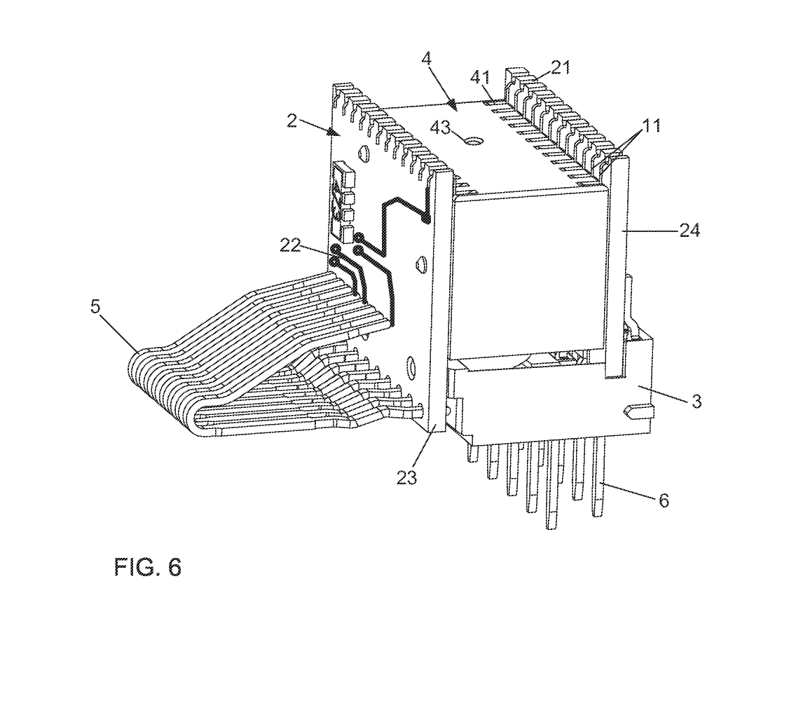

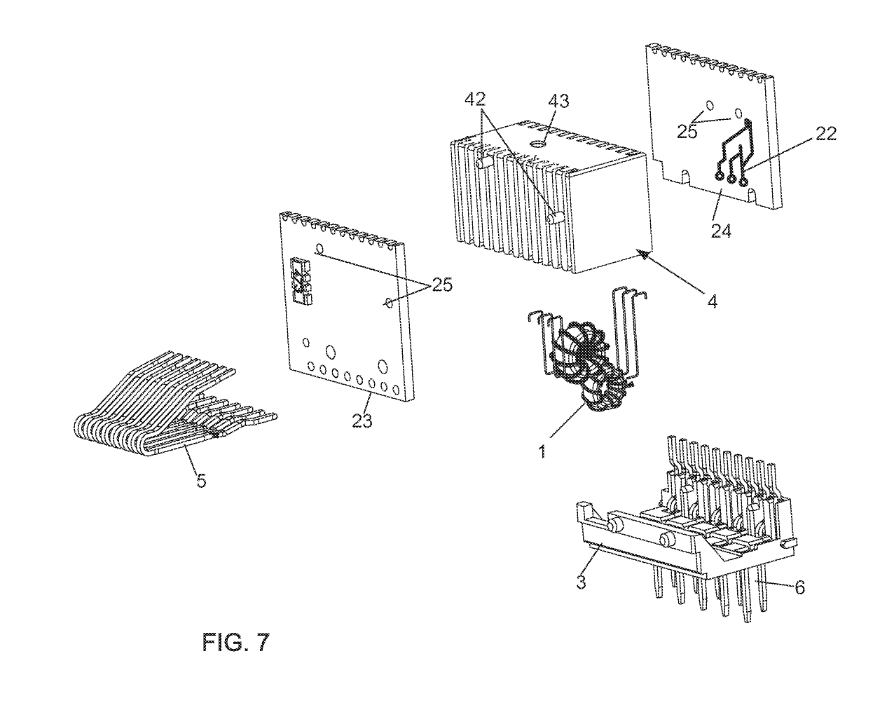

With reference to FIG. 6, which illustrates a stereo view of a third embodiment of the present invention. Moreover, please simultaneously refer to FIG. 7, there is shown an exploded view of the third embodiment of the present invention. As shown in FIG. 6 and FIG. 7, the third embodiment of the present invention consists of: a plurality of filter devices 1, two PCB 2 including an output PCB 23 and an input PCB 24, a base 3, a container 4, a plurality of electrical terminals 5, a plurality of input terminals 6, wherein the container 4 is connected to the base 3 for containing the filter devices 1, and the container 4 are provided with a plurality of grooves 41 on the two sides thereof, and has at least one exhaust opening 43. The metal lines of the filter devices 1 are disposed in the grooves 41 of the container 4, and the two PCBs 2 are disposed on the two sides of the container, such that the metal lines are extended out of the container 4 by respectively pass through the grooves 41, so as to electrically connect to the metal notches 21 of the PCB 2.

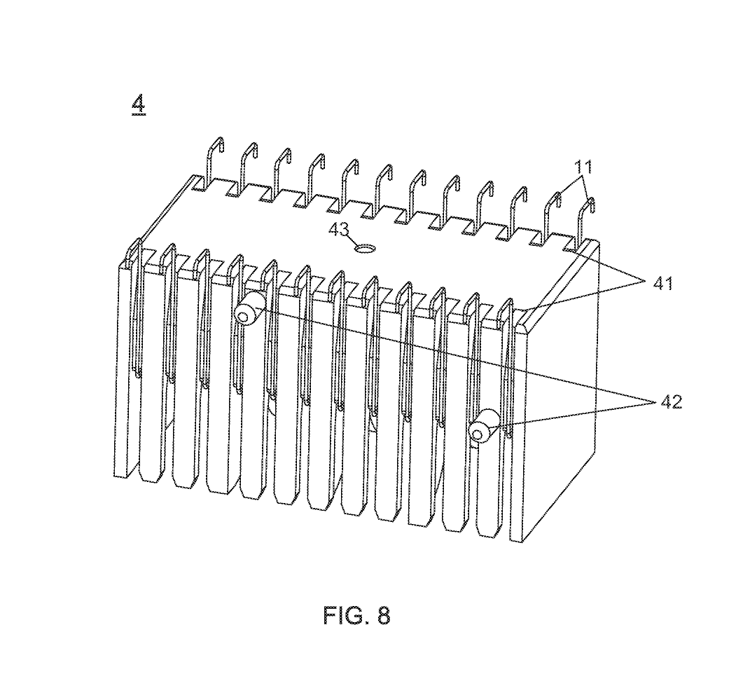

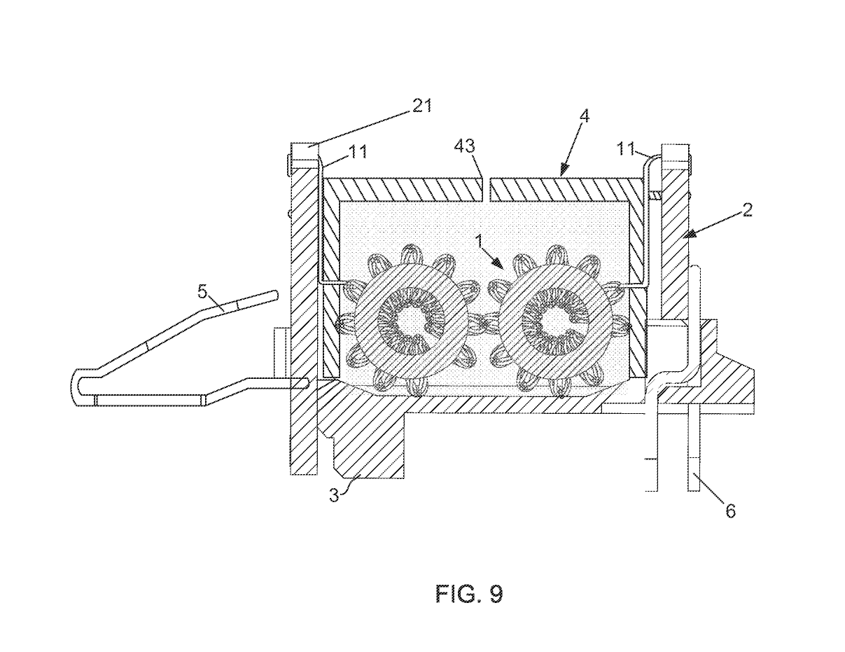

Continuously referring to FIG. 6 and FIG. 7, and please simultaneously refer to FIG. 8 and FIG. 9, there are respectively shown the stereo and cross-sectional views of the container 4. As shown in FIGs., the electrical terminals 5 are welded on the output PCB 23 of the PCB 2 for electrically connecting to the circuit layout 22 of the output PCB 23. On the other hand, the input terminals 6 are partially embedded on the base 3, wherein one end of the input terminals 6 is welded on the input PCB 24 for electrically connecting to the circuit layout 22 of the input PCB 24, and the other end of the input terminals 6 is downward extended out of the base 3. Besides, the container 4 is further provided with a plurality of heat-melting posts 42 on the two sides thereof, and the heat-melting posts 42 are respectively inserted into the fixing holes 25 formed between the input PCB 24 and the output PCB 23. When fabricating the assembly structure with the filter devices 1 and the PCB 2, it is able to simplify the manufacturing procedures and reduce the manufacturing cost by way of melting the heat-melting posts 42 for subsequently connecting the heat-melting posts 42 and the two PCB (23, 24) through glue joint.

Moreover, as shown in FIG. 9, when filling a colloidal substance into the container 4 for covering the filter devices 1 and fixing the metal lines 11, the air in the container 4 would flow out via the at least one exhaust opening 43, therefore container 4 is full of the colloidal substance. For enhancing the protection provided by the colloidal substance to the metal lines 11 and simultaneously increase the fabrication quality, the present invention particularly mixing a Varnish and a diluting agent with the mixing ratio of 1:2 to obtain a diluted Varnish solution for being as the colloidal substance.

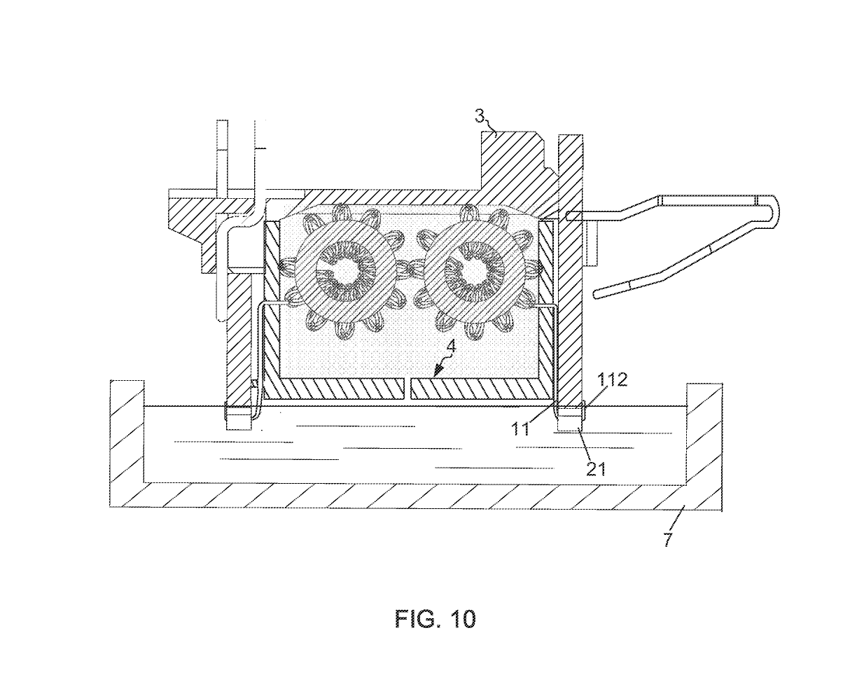

Continuously referring to FIG. 9, and please simultaneously refer to FIG. 10, which illustrates the cross-sectional view of the container 4 and a tin melting furnace 7. As shown in FIG. 9 and FIG. 10, the way to meld the metal lines 11 of the filter devices 1 with the metal notched 21 of the PCB 2 can be carried out through the following steps:

First of all, the filter devices 1 and the PCB 2 are disposed in the container 4 and on the two sides of the container 4, respectively. And then, the metal lines 11 of the filter devices 1 are respectively received by the metal notches 21 so as to contact with the metal notches 21. Subsequently, filling the colloidal substance into the container 4 for covering the filter devices 1 and fixing the metal lines 11; therefore, a laser beam is applied to the metal lines 11 respectively contacting with the metal notches 21 for removing the insulation layers 111 respectively covering the metal lines 11, such that the copper lines 112 of the metal lines 11 are exposed out. Eventually, to dispose the PCB 2 into the tin melting furnace 7 for treating the copper lines 112 and the metal notches 21 with a dip soldering process for respectively welding copper lines 112 with the metal notches 21.

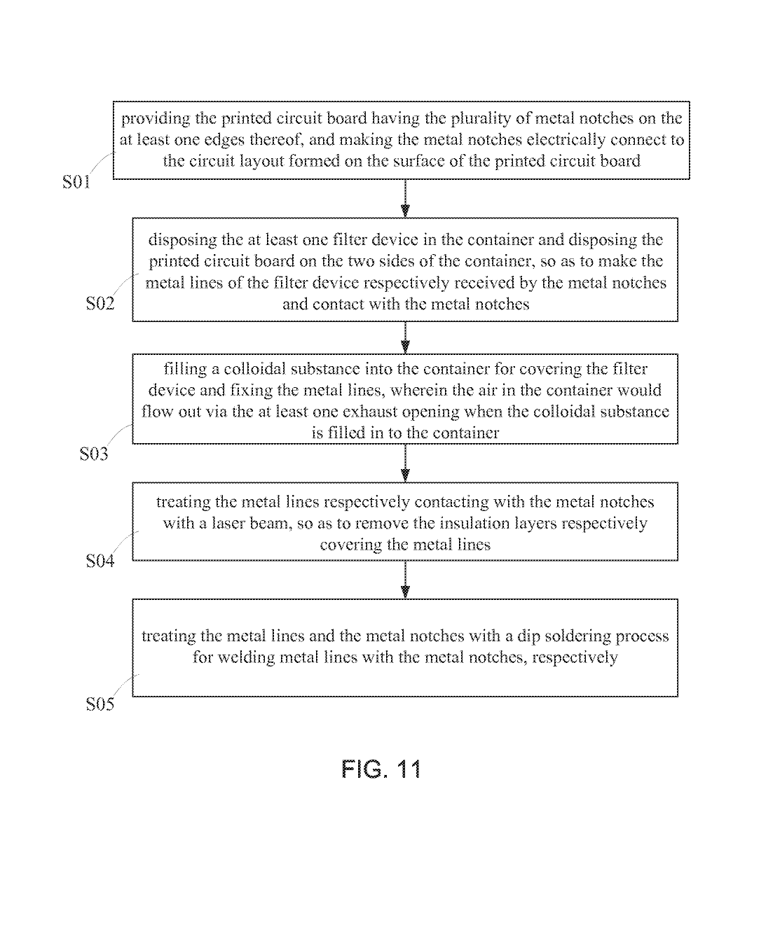

As the flow chart shown by FIG. 11, the welding way described above can be further explain by process flow steps as follows: (S01): providing the printed circuit board having the plurality of metal notches on the at least one edges thereof, and making the metal notches electrically connect to the circuit layout formed on the surface of the printed circuit board; (S02): disposing the at least one filter device in the container and disposing the printed circuit board on the two sides of the container, so as to make the two metal lines of the filter device respectively received by the metal notches and contact with the metal notches; (S03) filling a colloidal substance into the container for covering the filter device and fixing the metal lines, wherein the air in the container would flow out via the at least one exhaust opening when the colloidal substance is filled in to the container; (S04) treating the metal lines respectively contacting with the metal notches with a laser beam, so as to remove the insulation layers respectively covering the metal lines; and (S05) treating the metal lines and the metal notches with a dip soldering process for welding metal lines with the metal notches, respectively. In above-mentioned steps (S01)˜(S05), it needs to bake the container 4 and then wait for the cooling of the container 4 before the step (S04) is executed, wherein the container 4 is baked under 100° C. for 1.5 hours.

Referring to FIG. 2 and FIG. 3 again, the use of the laser beam can not only remove the insulation layers 111 from the metal lines 11, but also avoid the circuit layout 22 on the PCB 2 from being damaged. Moreover, if the insulation layers 111 is made of low melting point materials, then the power of the laser beam can be reduced; so that, it is able to further lower the impact occurring on the circuit layout 22 when removing the insulation layers 111 from the metal lines 11.

Moreover, in the assembly structure with filter devices 1 and the PCB 2, each the filter device 1 is corresponding to a pair of metal noshes 21, and the spacing distant between any two pairs of metal noshes 21 adjacent to each other is equal to (or smaller than) the spacing distant between any two filter devices 1. Thus, when fabricating the assembly structure with the filter devices 1 and the PCB 2, the metal lines 11 of the filter devices 1 can be easily disposed in the metal notches 21 and respectively contact with the metal notches 21, and that can avoid the metal lines 11 from overlong and complex to across over the filter devices 1.

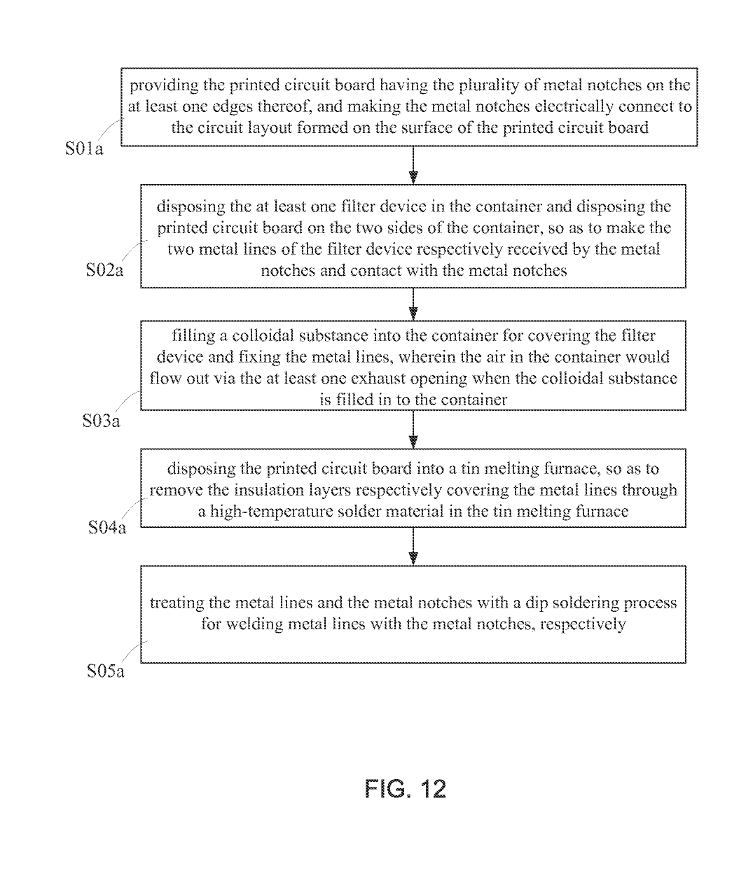

In addition, as the flow chart shown by FIG. 12, the present invention also proposes a second welding method for welding the metal lines 11 of the filter devices 1 with the metal notches 21 of the PCB 2, wherein the second welding method comprises the following steps:

(S01a): providing the PCB 2 having the plurality of metal notches 21 on the at least one edges thereof, and making the metal notches 21 electrically connect to the circuit layout 21 formed on the surface of the PCB 2; (S02a): disposing the filter devices 2 in the container 4 and disposing the PCB 2 on the two sides of the container 4, so as to make the metal lines 21 of the filter devices 1 respectively received by the metal notches 21 and contact with the metal notches 21; (S03a): filling a colloidal substance into the container 4 for covering the filter devices 2 and fixing the metal lines 11, wherein the air in the container 4 would flow out via the at least one exhaust opening 43 when the colloidal substance is filled in to the container 4; and (S04a): disposing the PCB 2 into a tin melting furnace, so as to remove the insulation layers 111 respectively covering the metal lines 11 through a high-temperature solder material in the tin melting furnace; and (S5a): treating the copper lines 112 and the metal notches 21 with a dip soldering process for welding copper lines 112 with the metal notches 21, respectively. In above-mentioned steps (S01a)˜(S05a), it needs to bake the container 4 and then wait for the cooling of the container 4 before the step (S04a) is executed, wherein the container 4 is baked under 100° C. for 1.5 hours.

Through above descriptions, the assembly structure with filter devices 1 and PCB 2 and the welding method for making the same have been clearly and completely introduced; in summary, the assembly structure and the welding method includes the following advantages:

In the present invention, the welding method is firstly make the metal lines 11 of at least one filter devices 1 be disposed in the metal notches 21 formed on at least one edges of the printed circuit board (PCB) 2, and then respectively removing the insulation layers 111 covering the metal lines 11; therefore, the welding metal lines 11 can be respectively welded with the metal notches 21 after the metal lines 11 and the metal notches 21 are treated with a dip soldering process. Thus, the welding process of the filter devices 1 and the PCB 2 can be carried out on the edges of the PCB 2 by simple process procedures; moreover, the fabrication yield of the assembly structure with the filter devices and the PCB 2 can be effectively increased, and the manufacturing time and cost of the assembly structure can be simultaneously reduced.

The above description is made on embodiments of the present invention. However, the embodiments are not intended to limit scope of the present invention, and all equivalent implementations or alterations within the spirit of the present invention still fall within the scope of the present invention.

What is claimed is:

1. An assembly structure with filter device and printed circuit board, comprising:
at least filter device, having a plurality of metal lines covered by an insulation layer;
at least one printed circuit board, being provided with a plurality of metal notches on at least one edge thereof, and being formed with a circuit layout on the surface thereof;
wherein the metal notches are electrically connected to the circuit layout, and the metal lines being disposed in the metal notches, respectively;
wherein the metal lines are respectively welded in the metal notches by way of dip soldering process after removing the insulation layers from the metal lines.

2. The assembly structure with filter device and printed circuit board of claim 1, wherein the metal notch is disposed with a copper sheet or coated with a copper layer.

3. The assembly structure with filter device and printed circuit board of claim 2, wherein each the filter device comprises two metal lines, and the metal lines being respectively welded in the metal notches after the filter device is disposed on the printed circuit board.

4. The assembly structure with filter device and printed circuit board of claim 2, further comprising:
a base; and
a container, being connected to the base for containing the filter devices, wherein the container are provided with a plurality of grooves on the two sides thereof, and has at least one exhaust opening.

5. The assembly structure with filter device and printed circuit board of claim 4, wherein the printed circuit board is deposed on one side of the container for making the metal lines respectively passing through the grooves so as to electrically connect with the metal notches.

6. The assembly structure with filter device and printed circuit board of claim 5, further comprising:
a plurality of electrical terminals, being welded on the printed circuit board for electrically connecting to the circuit layout; and
a plurality of input terminals, being partially embedded on the base, wherein one end of the input terminals is welded on the printed circuit board for electrically connecting to the circuit layout, and the other end of the input terminals is downward extended out of the base.

7. The assembly structure with filter device and printed circuit board of claim 4, wherein the at least one filter device and the printed circuit board are welded by using following welding steps:
(1) providing the printed circuit board having the plurality of metal notches on the at least one edges thereof, and making the metal notches electrically connect to the circuit layout formed on the surface of the printed circuit board;
(2) disposing the at least one filter device in the container and disposing the printed circuit board on the two sides of the container, so as to make the metal lines of the filter device respectively received by the metal notches and contact with the metal notches;
(3) filling a colloidal substance into the container for covering the filter device and fixing the metal lines, wherein the air in the container would flow out via the at least one exhaust opening when the colloidal substance is filled in to the container;
(4) treating the metal lines respectively contacting with the metal notches with a laser beam, so as to remove the insulation layers respectively covering the metal lines; and
(5) treating the metal lines and the metal notches with a dip soldering process for welding metal lines with the metal notches, respectively.

8. The assembly structure with filter device and printed circuit board of claim 4, wherein the at least one filter device and the printed circuit board are welded by using following welding steps:
(1a) providing the printed circuit board having the plurality of metal notches on the at least one edges thereof, and making the metal notches electrically connect to the circuit layout formed on the surface of the printed circuit board;
(2a) disposing the at least one filter device in the container and disposing the printed circuit board on the two sides of the container, so as to make the two metal lines of the filter device respectively received by the metal notches and contact with the metal notches;
(3a) filling a colloidal substance into the container for covering the filter device and fixing the metal lines, wherein the air in the container would flow out via the at least one exhaust opening when the colloidal substance is filled in to the container;
(4a) disposing the printed circuit board into a tin melting furnace, so as to remove the insulation layers respectively covering the metal lines through a high-temperature solder material in the tin melting furnace; and
(5a) treating the metal lines and the metal notches with a dip soldering process for welding metal lines with the metal notches, respectively.
